(19) United States
(12) Patent Application Publication
(10) Pub. No.: US 2015/0048434 A1
(43) Pub. Date: Feb. 19, 2015

(54) Structure and Method of Manufacturing a Stacked Memory Array for Junction-Free Cell Transistors

(71) Applicant: Conversant Intellectual Property Management Inc., Ottawa (CA)

(72) Inventor: Hyoung Seub Rhie, Ottawa (CA)

(73) Assignee: Conversant Intellectual Property Management Inc, Ottawa (CA)

(21) Appl. No.: 13/969,058

(22) Filed: Aug. 16, 2013

(51) Int. Cl. H01L 29/78; H01L 21/28

(52) U.S. Cl. CPC H01L 29/78; H01L 21/28008
USPC 257/314; 438/586

(57) ABSTRACT

A three-dimensional NAND memory device and an associated method for manufacturing this device are provided. The three-dimensional NAND memory device includes a source contact electrically isolated from a conductive gate material. The source contact also electrically connects a conductive source line to a first silicon strip and a second silicon strip through the conductive gate material.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Non-volatile memory such as flash memory is widely employed in consumer electronics and storage applications, e.g., USB flash drivers, portable media players, cell phones, digital cameras, etc. Two common types of flash memory are NOR and NAND flash memories. NOR flash memory provides a full address and data interface that allows random access to any location, whereas NAND flash memory typically provides faster erase and write times, higher density, and lower cost per bit.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 is a schematic diagram illustrating NAND flash cell transistors.

FIG. 2 is another schematic diagram illustrating NAND flash cell transistors.

FIG. 3 is a schematic diagram illustrating elements of a NAND flash cell array.

FIG. 4 is a simplified view of a structure of the NAND flash cell array.

FIG. 5 is a simplified view of a structure of one NAND flash block.

FIG. 6 is a simplified view of a structure of one NAND flash page.

FIG. 7 is a schematic diagram of a vertical channel NAND flash device.

FIG. 8 is a schematic diagram of a vertical gate NAND flash device.

FIG. 9 is a schematic diagram of a vertical gate NAND flash.

FIG. 10 is a layout and schematic diagram of a vertical gate NAND with staggered even/odd direction strings.

FIG. 11 is a layout and schematic diagram of a vertical gate NAND according to an embodiment of the present disclosure.

FIG. 12 is a schematic diagram of a vertical gate NAND according to an embodiment of the present disclosure.

FIG. 13 is a schematic diagram of cutlines in a vertical gate NAND according to an embodiment of the present disclosure.

FIG. 14 is a schematic diagram of cross sections along the cutlines of FIG. 13 according to an embodiment of the present disclosure.

FIG. 15 is a schematic diagram of conducting string channels according to an embodiment of the present disclosure.

FIG. 16 is a schematic diagram of cell stack and through-string contact formation according to an embodiment of the present disclosure.

FIG. 17 is a schematic diagram of cell stack patterning according to an embodiment of the present disclosure.

FIG. 18 is a schematic diagram of gate dielectric deposition according to an embodiment of the present disclosure.

FIG. 19 is a schematic diagram of gate material and interlayer dielectric deposition according to an embodiment of the present disclosure.

FIG. 20 is a schematic diagram of contact patterning according to an embodiment of the present disclosure.

FIG. 21 is a schematic diagram of contact side wall spacer deposition according to an embodiment of the present disclosure.

FIG. 22 is a schematic diagram of a sidewall spacer etch back according to an embodiment of the present disclosure.

FIG. 23 is a schematic diagram of source line formation and inter-metal dielectric deposition according to an embodiment of the present disclosure.

FIG. 24 is a schematic diagram of source contacts not completely surrounded by gates according to an embodiment of the present disclosure.

FIG. 25 is a schematic diagram where spaces between SSL and GSL are not reduced according to an embodiment of the present disclosure.

### DETAILED DESCRIPTION

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

The present disclosure generally relates to a nonvolatile memory, such as a flash memory device. The flash memory may comprise NAND Flash memory and other types of flash memories. More particularly, the present disclosure relates to a three-dimensional, vertical gate NAND memory array and a method for manufacturing such a memory array.

Flash memory is a commonly used type of nonvolatile memory in widespread use as mass storage for consumer electronics, such as digital cameras and portable digital music players. Such flash memories can take the form of memory cards or USB type memory sticks, each having at least one memory device and a memory controller formed therein.

The need to reduce manufacturing costs per data bit is driving the NAND Flash industry continuously to reduce the size of the cell transistors. Due to the limitations imposed by photolithography tools and the limits of shrinking the physical transistor size, schemes have been proposed whereby NAND cells are stacked in a direction perpendicular to the chip surface. The effective chip area per data bit can thereby be reduced without relying on shrinkage of the physical cell transistor size. Embodiments of the present disclosure apply to vertically stacked NAND Flash transistor cells.

A brief description of NAND Flash cells, cell organization, and vertically stacked NAND cell technology will be given to define terms used in the present disclosure. The description serves as an example and is not to be understood as limiting the present disclosure to any specific cell transistor structure or organization.

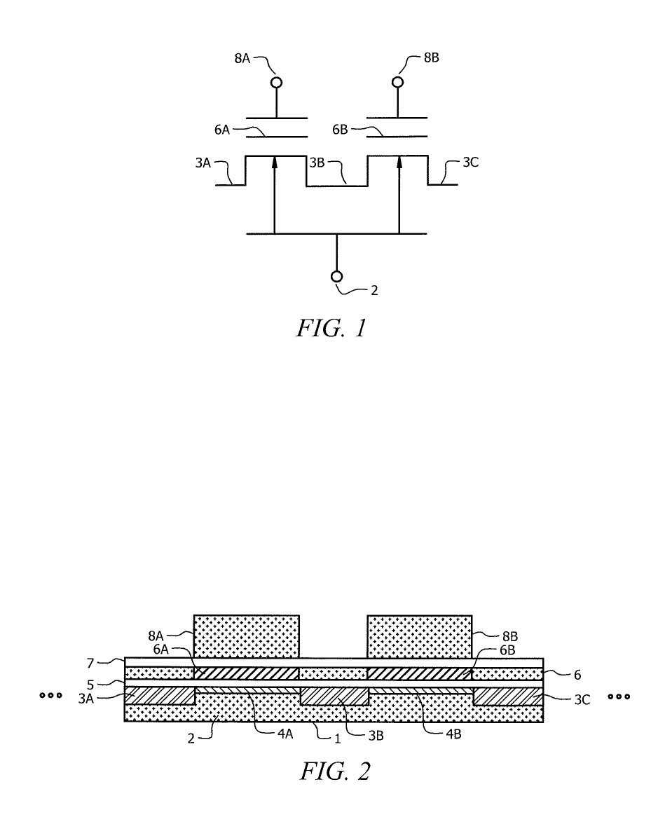

Some basic elements of a NAND Flash cell which are common to all NAND Flash technologies will be described using FIG. 1 and FIG. 2, whereby the figures and the related descriptions are understood not to limit the present disclosure to any specific technology or device structure, but only serve as illustrations to define terms for later use in the present disclosure.

FIG. 1 shows a schematic with two NAND Flash cell transistors serially connected to each other. The two transistors comprise control gates 8A/8B, floating nodes (or storage nodes) 6A/6B, source/drain nodes 3A-3C, and the cell body node 2.

An example vertical structure of this schematic is shown in FIG. 2. A typical NAND Flash cell is manufactured on a semiconductor substrate 1, for example monocrystalline or polycrystalline silicon. The substrate 1 forms the body node of the cells, which is a p-well in most conventional NAND Flash cells. Although not shown in the figure, the semiconductor substrate 1 is sometimes manufactured on a dielectric material so as to form a silicon-on-insulator (SOI) structure.

A multi-layered gate dielectric 5-7 is formed on the semiconductor substrate 1. The multi-layered gate dielectric consists of a tunnel dielectric layer 5, a charge storage layer 6, which is formed on the tunnel dielectric, and a coupling dielectric 7 (also called a blocking dielectric depending on the technology), which is manufactured on the charge storage layer. This charge storage layer may be a so-called charge trap layer which contains the locations where electrons are trapped (6A/6B). In the case of floating gate technology (not shown), the charge storage layer does not form a continuous film but is patterned into separate floating gates, where the floating gate of each cell is isolated from the floating gates of adjacent cells. In the case of charge trap technology, as shown in the figure, isolation of charge storage nodes from each other and patterning of the overall multi-layer gate dielectric may or may not be performed, as charge flow between adjacent charge storage nodes is impeded due to the dielectric nature of the charge trap layer even if charge storage nodes are not isolated from each other by way of patterning. The gate dielectric consisting of the tunnel dielectric 5, the charge storage layer 6, and the coupling dielectric 7 may thus be manufactured as a continuous thin film without patterning the gate dielectric into multiple isolated pieces. Alternatively, the gate dielectric may be patterned into multiple isolated pieces in some other devices. Control gates 8A/8B are manufactured on the coupling dielectric. The charge trap technology may be a so-called S(silicon)-O(silicon oxide)-N(silicon nitride)-O(silicon oxide)-silicon technology.

The silicon substrate 1 contains the source/drain regions 3A-3C. In some older schemes, the source/drain regions consist of implanted or diffused regions with n-type doping (n+ source/drain). In some more recent schemes, the source/drain regions are not formed through ion implantation as permanently conducting regions, but the conductivity is controlled by electric fringe-fields from the control gates 8A/8B, whereby a high enough bias at the control gates 8A/8B can induce conductive inversion layers in the source/drain regions 3A-3C in the same manner as a channel inversion layer forms when a transistor is turned on. These types of cells may be referred to as “junction-free” or “junctionless” cells.

It is to be understood that, for the junctionless technology applied throughout this disclosure, the channel regions 4A/4B are in a conductive state only if the electric field between the charge storage node and the substrate is high enough to induce an inversion layer. This electric field is caused by a combination of the charge stored in the charge storage layer and the external bias that is applied to the control gate.

The physical mechanisms as well as biasing conditions for read, program, and erase operation of NAND Flash cells are described in a cursory manner with reference to the left cell transistor in FIG. 1 and FIG. 2.

Electrons trapped in the charge storage node 6A of a cell transistor modify the threshold voltage of this cell transistor to different levels depending on the data (0 or 1) stored in the cell. The threshold voltage of the cell transistor determines the resistance of the channel 4A. In some common embodiments, memory cells store two logic states, data ‘1’ and data ‘0’, and each memory cell corresponds to one bit. In this case, the flash memory cell can have one of two threshold voltages corresponding to data ‘1’ and data ‘0’. In some other widely used NAND Flash devices, cells can also be programmed to have more than two threshold levels, and thus multiple bits can be stored in one physical cell. Such cells are referred to as MLC (multi-level cells). Even if no explicit reference is made to single or multiple bit storage, examples of the disclosed techniques may apply equally to NAND memory devices with single and multiple bit storage per cell.

Typically, a NAND flash memory cell is erased and programmed by Fowler-Nordheim (F-N) tunneling. In some widely used program operation schemes, the control gate 8A of a cell is biased to a highly positive program voltage, Vpgm, for example 20V, while the substrate 2, source and drain 3A/3B of the cell are biased to Vss (ground). More precisely, the high Vpgm voltage induces a channel 4A under the tunnel dielectric 5. Since this channel is electrically connected to the source and drain, which are tied to Vss=0V, the channel voltage, Vch, is also tied to ground. By the difference in voltage Vpgm−Vch, electrons from the channel are uniformly injected to the floating node 6A through the tunnel dielectric. The cell threshold voltage, Vth, of the programmed cell is shifted in the positive direction.

In order to read cell data, the control gate 8A is biased to 0V. If the cell is in an erased state, the erased cell has a negative threshold voltage, and thus a cell current (Icell) from the drain 3B to the source 3A flows under some given read bias conditions. Similarly, if the cell is in a programmed state, the programmed cell has a positive threshold voltage, and there is no cell current from the drain 3B to the source 3A under read bias condition. An erased cell (on-cell) is sensed as data ‘1’ and a programmed cell (off-cell) is sensed as data ‘0’.

During an erase operation, the control gate 8A of a cell is biased to Vss (ground) while the cell body 2 is biased to an erase voltage, V_erase, (e.g., 18 V), and the source and drain 3A/3B of the cell are floated. No conductive inversion layer channel 4A of n-type conductivity exists in erase bias conditions because the cell transistors are strongly turned off. With this erase bias condition, trapped electrons in the floating node 6A are emitted uniformly to the substrate 2 through the tunnel dielectric 5. The cell threshold voltage (Vth) of the erased cell becomes negative. In other words, the erased cell transistor is in an on-state if the gate bias of the control gate is 0V. Erase operation is not applied to single cells in NAND Flash memory but to entire erase blocks, which will be defined below.

The basic cell array organization of NAND flash memory devices will now be described. The figures and the related description should be understood to serve only as an example to define terms for later use in the present disclosure and should not be understood as specific to any technology or device structure. The disclosure is not to be understood to apply only to the shown array organization.

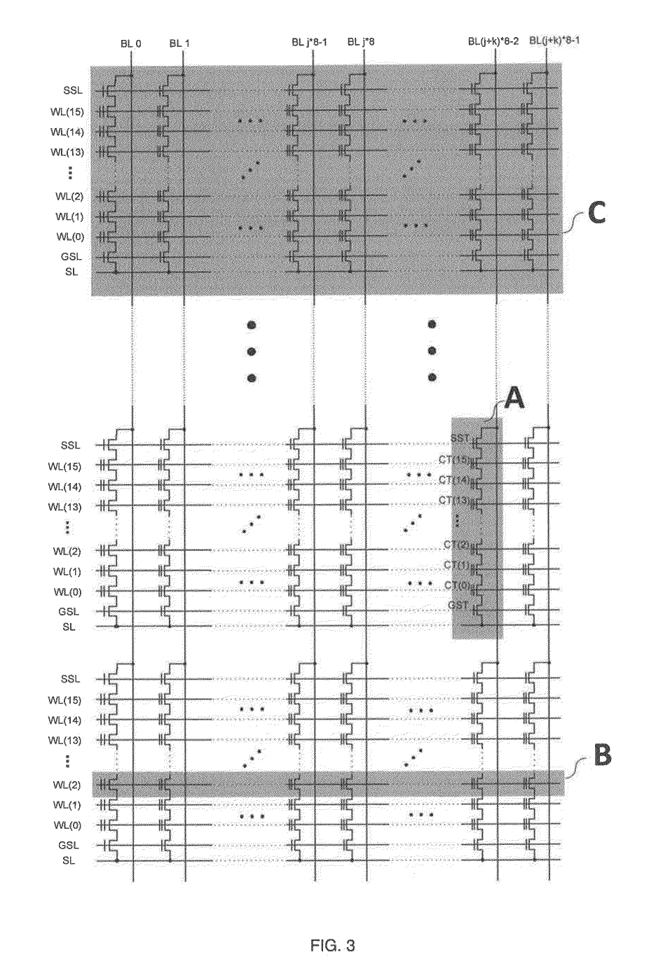

FIG. 3 serves as an illustration to describe the terms “string”, “page” and “block” in a NAND Flash memory device. A NAND cell string as illustrated in the shaded box “A” of FIG. 3 consists of at least one string select transistor (hereinafter referred to as SST, SSL gate, or SSL transistor), which is placed in series with the cell transistors (CT) and one terminal (hereinafter referred to as the drain) being connected to a bit line. A NAND cell string also contains a certain number of memory cell transistors (CT) and at least one ground select transistor (hereinafter referred to as GST, GSL gate, or GSL transistor), which is serially connected between the cell transistors and a source line.

Although in this figure a string consists of 16 cells, the present disclosure is not restricted to any specific number of cells per string. The number of cells per string may vary, with 4 cells per string, 8 cells per string, 32 cells per string, 64 cells per string, 128 cells per string, or any other number greater than one also being possible embodiments.

Memory cell gates in FIG. 3 are coupled to word lines (commonly abbreviated WL in the embodiments of the disclosure) 0 to 15. The gate of a string select transistor (SST) is connected to a string select line (SSL) while the drain of a string select transistor (SST) is connected to a bit line (BL). The gate of a ground select transistor (GST) is connected to a ground select line (GSL) while the source of the ground select transistor (GST) is connected to a source line (SL or CSL). A gate layer to which the gate of a ground select transistor is connected may be referred to hereinafter as a GSL, but it should be understood that different manufacturers may refer to such a gate layer by different names.

To specify a direction within a string, the direction towards the SSL of a string will be referred to as “drain direction” or “drain side”, and the direction towards the GSL of a string will be referred to as “source direction” or “source side” hereinafter.

The shaded box “B” in FIG. 3 illustrates a possible embodiment of a page in a NAND Flash device. A page is the smallest unit addressed by a row address. The smallest unit for which a read or program operation can be performed is also one page. In some common embodiments, one page is identical to all cells connected to one word line. However, other embodiments also exist where cells connected to a certain word line are subdivided into multiple subgroups, which thus constitute multiple pages per word line, whereby each one of the multiple pages in one word line has a different row address. In the case of multiple bit storage in one physical cell, different bits can belong to different pages logically although they are physically located in the same cell transistor and thus connected to the same word line. Hereinafter, the disclosed techniques will be described using, but are not restricted to, the example in FIG. 3 where each word line corresponds to one page.

The shaded box “C” in FIG. 3 illustrates the meaning of a cell block. The cell block is constituted by the entirety of strings that share the same word lines, string select lines, and ground select lines. In the most common embodiments of NAND Flash memory devices, the smallest unit for which an erase operation is performed is one cell block, which is therefore often called an “erase block”.

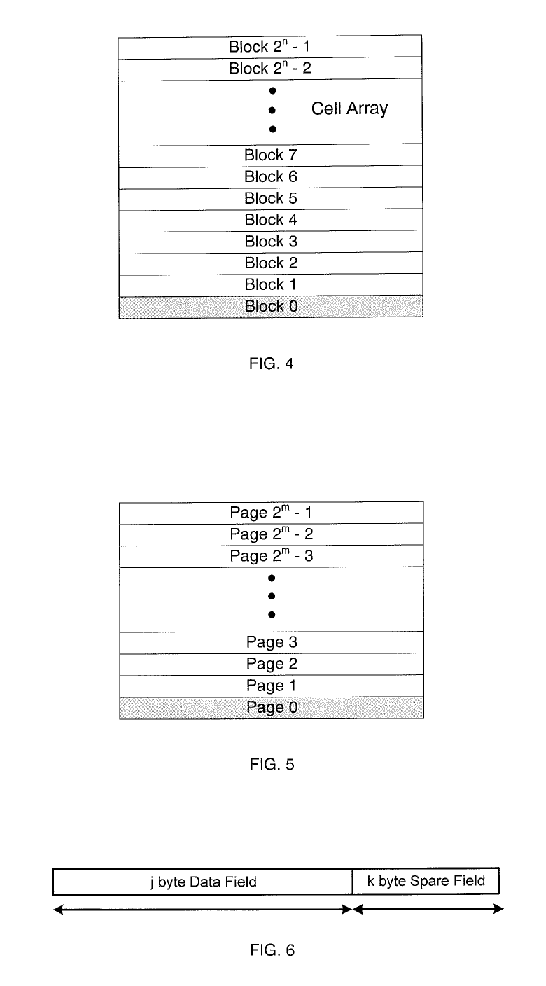

Assuming that the row address is made of n bits for the block address and m bits for the page address, FIG. 4 illustrates the cell array structure of NAND flash memory. The structure consists of 2n erase blocks, with each block subdivided into 2m programmable pages as shown in FIG. 5.

Each page consists of (j+k) bytes (times 8 bits) as shown in FIG. 6. The pages are further divided into a j-byte data storage region (data field) with a separate k-byte area (spare field). The k-byte area is typically used for error management functions. Therefore, the following relationships exist: 1 page=(j+k) bytes; 1 block=2m pages=(j+k) bytes*2m; and total memory array size=2n blocks=(j+k) bytes*2m+n.

The need to reduce manufacturing costs per data bit is driving the NAND Flash industry continuously to reduce the size of the cell transistors. Due to the limitations imposed by photolithography tools and the limits of shrinking the physical transistor size, schemes have been proposed whereby NAND cells are stacked in a direction perpendicular to the chip surface. The effective chip area per data bit can thereby be reduced without relying on shrinkage of the physical cell transistor size. Embodiments of the present disclosure may apply specifically to vertically stacked NAND Flash transistor cells.

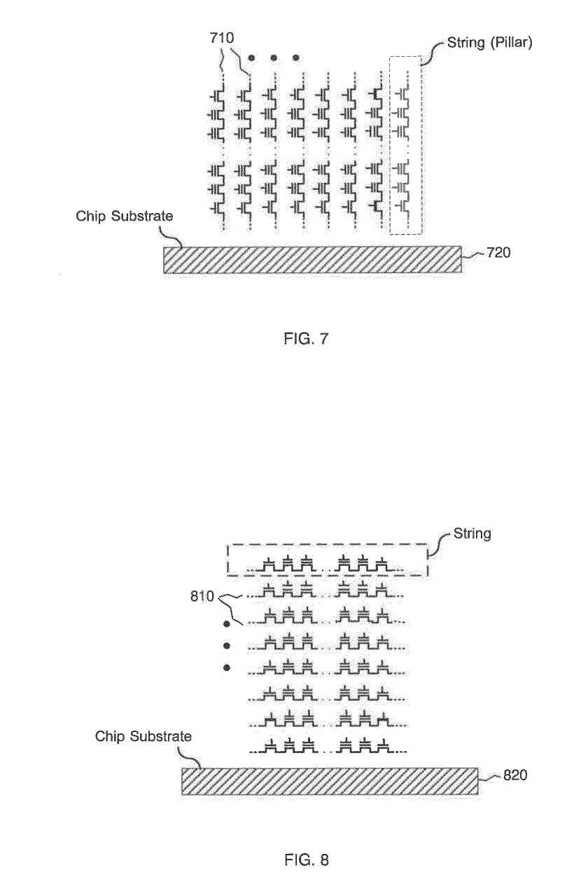

From a geometrical point of view, two different types of stacked NAND devices exist. In case (1), shown in FIG. 7, cell strings 710 run in a direction perpendicular to the chip substrate 720, and cells that belong to the same string are stacked vertically on top of each other. In case (2), shown in FIG. 8, cell strings 810 run in a direction parallel to the chip substrate 820. Cells that belong to the same string are aligned in a direction parallel to the chip surface as in conventional NAND cells, and different strings are stacked vertically on top of each other.

Following the convention of related literature, case (1) NAND Flash will be referred to as Vertical Channel NAND or VC NAND hereinafter, and case (2) NAND Flash will be referred to as Vertical Gate NAND or VG NAND hereinafter, regardless of the specific details of the cell transistor internal structure.

Embodiments of the present disclosure apply to case (2) VG NAND structures, where the conductive strips which form the silicon bodies of the individual strings run as silicon strips horizontal to the chip surface as in FIG. 8. Typical features of VG NAND will now be described.

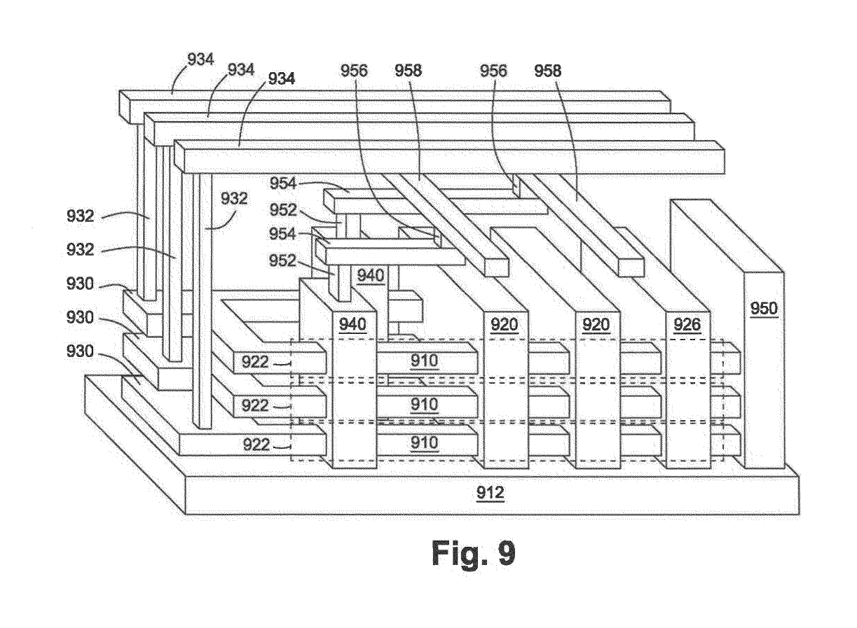

FIG. 9 shows a typical array architecture of VG NAND. In such a VG NAND and in embodiments of the present disclosure, the silicon strips comprising channels 910 of NAND strings 922 run in a horizontal direction above silicon substrate 912, whereas the NAND strings 922 are stacked on top of each other so as to form a stack of strings. The cell transistors are formed as dual gate devices with channels existing on the sidewalls and gates also facing the sidewalls of the silicon strips which constitute the strings. Transistors within the strings do not have any implanted diffused n+ region as sources/drains, except for the drain of the SSL transistors on the bit line pad side and the source of the GSL transistors at the source side of the string in the region of a Ground Select Line (GSL) 926. That is, the string transistors form junctionless transistors with virtual sources/drains, where the conductivity of source/drain regions depends on the existence of electric fringe fields between gates adjacent to the source/drain regions and the source/drain silicon itself. Word lines 920 connect gate nodes of cell transistors in a horizontal direction as in conventional planar NAND cell technology. In addition, any cell transistor shares its gate node with all cell transistors that are located in a vertical direction from it. Multiple strings belonging to the same stacked layer (but no strings belonging to different stacked layers) share a common bit line (one of the bit lines 934 in Metal Layer Three) and are connected to the common bit line via a respective one of the bit line pads 930 and a respective one of the via contacts 932.

Contrary to the word lines 920, SSL gates 940 (SSL islands 940) are island-shaped, so that each string shares a common SSL gate 940 with all strings that are located above or below it in a vertical direction, but not with any string that is located in a horizontal direction from it. Also, as shown in the illustrated example, each of the SSL islands 940 is connected to a respective String Select Line (SSL) 958 in Metal Layer Two as follows: the SSL island 940 is connected to a respective via contact 952, which is in turn connected to a respective Metal Layer One path 954, which is in turn connected to a respective via contact 956, which is in turn connected to the respective String Select Line (SSL) 958 in Metal Layer Two. Contrary to the drain node of each string, which is shared only horizontally with other strings via a bit line pad 930 but not vertically, the source node of each string is shared with adjacent strings that are located above or below it in a vertical direction via a source contact (Common Source Line 950 in the figure).

Other features shown in FIG. 9 that are not listed above may not be common features of all VG NAND architecture but may be specific only to the device shown in the figure and therefore may vary among different embodiments of VG NAND architecture. These varying features may include whether or not the source contact (“Common Source Line” 950 in the figure) is manufactured in a plate-shape and shared in a horizontal direction as shown in the figure; whether the source contact runs as a gate layer in a horizontal direction or whether the source contact connects vertically to an additional metal line which runs in a horizontal direction; the directional orientation of the strings, that is, whether the strings all run in the same direction or even/odd strings run in opposite directions; the exact way SSL islands are aligned and bit line pads are connected to metal layers through via contacts; methods of reducing the word line resistance (WSix); and the charge storage technology (ONO, floating gate technology, etc.) and specific materials used for the device.

Some of the variations will become more apparent with the description of a different scheme and with the description of the embodiments of the present disclosure. In the given examples as well as throughout the descriptions in this disclosure, it is assumed that NAND cell transistors consist of n-channel transistors on a p-type (or undoped) substrate. However, this is not a necessary requirement of the disclosed embodiments. For example, n- and p-type impurities may be interchanged so as to form p-channel transistors on an n-type substrate, or the substrate may consist of undoped silicon.

Embodiments of the present disclosure provide a layout, vertical structure, and manufacturing method for easing the node isolation of adjacent island-type SSL gates in VG NAND. Node isolation of adjacent island-type SSL gates by way of lithographic patterning may be difficult to perform at narrow string pitches. Some standard methods have been proposed to ease the difficulty of manufacturing. One such method involves performing node isolation of adjacent SSL gates by way of self-alignment instead of photolithographic patterning. Another such method involves aligning island SSL gates in a zigzag pattern as also shown in FIG. 9, instead of aligning the SSL gates in a straight line to effectively create double pitch. Yet another such method involves arranging strings in an alternating even/odd oriented layout so that double pitch is available for fitting in island SSL gates.

While such proposed schemes may ease the difficulty of narrow pitch manufacturing, in the specific case of VG NAND technology, such proposed schemes may introduce new issues not present before the introduction of these schemes. Specifically regarding the third solution above (even/odd string orientation), it will become more apparent with the description of the specific scheme used in that solution and with the description of embodiments of the present disclosure that specific proposed layouts may introduce new problems that will be addressed by the present disclosure.

The following description of a scheme shows a specific embodiment of the even/odd string orientation technique for easing the difficulty of narrow pitch island SSL gate manufacturing. FIG. 2b) on p. 2.3.3. of “A Highly Scalable 8-layer Vertical Gate 3D NAND with Split-page Bit Line Layout and Efficient Binary-sum MiLC (Minimal Incremental Layer Cost) Staircase Contacts”, Electron Devices Meeting (IEDM), 2012 IEEE International, by S.-H. Chen et al., which is incorporated herein by reference, shows a top view of the bit line pad region of the above-mentioned alternating orientation where even/odd strings are arranged in opposite directions. Island-type SSL gates are manufactured in a pitch twice as wide as the string pitch.

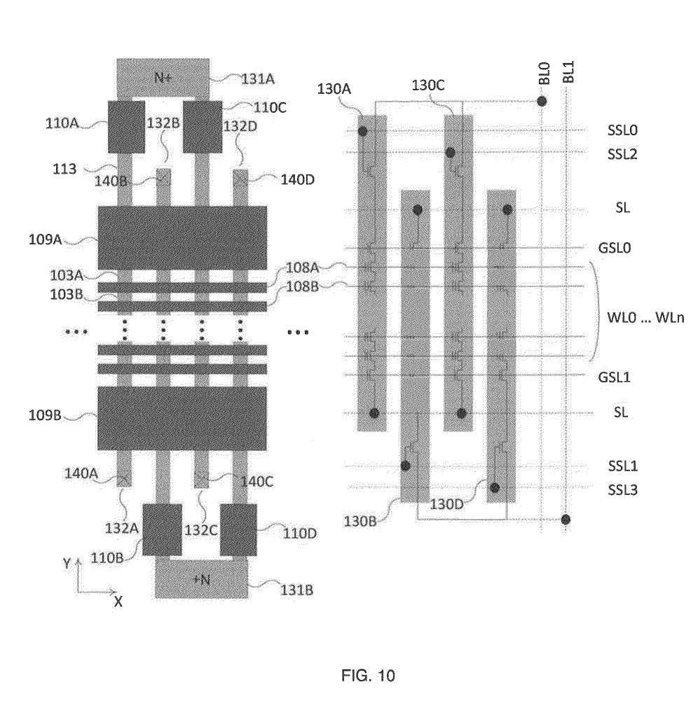

For better clarity and easier comparison with certain embodiments of the present disclosure, some features of the S.-H. Chen scheme are repeated in the simplified picture on the left side of FIG. 10, where only two even and two odd strings are shown. For reasons of simplicity, FIG. 10 focuses on the layout of electrically conductive elements and omits details on the cell structure, dielectric layers, gate dielectrics, charge storage layers, etc. The right side of the figure shows the schematic corresponding to the layout. It is to be understood that FIG. 10 shows only one layer out of a plurality of layers that are stacked vertically in a manner similar to that in FIG. 9.

The scheme in FIG. 10 shares most features of VG NAND described above as common features. However, specific to this scheme, even strings 130A/1300 and odd strings 130B/130D run in opposite directions alternatingly and are connected to even bit line pads 131A and odd bit line pads 131B alternatingly. Due to this even/odd layout, there also exist even GSL lines 109A and odd GSL lines 109B. As even and odd GSL lines run in the horizontal X-direction and are shared by even and odd strings alike, each string has a GSL gate at the source side (as in most conventional NAND devices) but also on the drain side.

Since the source ends of even (odd) strings 132A/C (132B/D) are individually located between odd (even) strings 130B/D (130A/C) on either side in the X-direction, the source contacts 140A-140D are not formed as a plate-shaped common source line as in FIG. 9, which connects adjacent string sources vertically as well as horizontally. Rather, the source contacts 140A-140D of odd (even) strings 130B/D (130A/C) are formed as individual contacts and located between adjacent even (odd) strings 130A/C (130B/D), and not as horizontal plate-shaped connections as in FIG. 9. The source contacts 140A-140D are located between SSL gates 110A-110D and GSL gates 109A/B in the Y-direction. A horizontal connection between the individual source contacts in the X-direction exists via a source line (SL), which is not shown in the layout on the left side of FIG. 10, but is shown in the schematic on the right side of the figure as a dashed line.

In spite of easing the manufacturing of SSL gates, in this scheme there exist at least three issues for which an improved scheme will be disclosed herein. First, it is apparent that the spaces 113 between the SSL 110A-110D and GSL gates 109A/B in the Y-direction are significantly larger than the spaces between any other gates within the strings, e.g., the width source/drain regions 103B between the word lines 108A/B or between the GSL and the word lines. It may be apparent to one skilled in the art that the reason this space 113 cannot be narrowed down to the limit attainable by the used lithography tool is because source contacts 140A-140D must not be electrically shorted to either the nearby SSL 110A-110D or GSL gates 109A/B. Rather, a sufficiently large distance needs to exist between SSL and GSL gates to allow for the space needed to fit in source contacts and leave a sufficient space margin between the source contacts and adjacent gates.

Commonly, this space margin would be determined by the misalign margin of the photolithographic tool and therefore would be larger than the minimum feature size of the applied process technology. Since the minimum space between the SSL and GSL gates would include the size of the source contact itself, the space between the contact and the SSL gate, and the space between the contact and the GSL gate, the minimum space between the SSL and the GSL would be larger than three times the minimum feature size.

Second, it is apparent that the source contacts are in close vicinity in the X-direction to the semiconductor surface of the source/drain node 113 of neighboring string bodies. That is, since any source contact 140A/C (140B/D) of an even (odd) string is located between two neighboring odd (even) strings 130B/D (130A/C) on either side, the contact is in close vicinity to the source drain region between SSL and GSL of either neighboring even (odd) string.

Third, the same issues that exist for the source/drain nodes 113 also exist vice versa to some extent for the source nodes 132A-D. The source nodes 132A-D, too, may be located in a wide space far from the next gate, and the source nodes 132A-D, too, are in close vicinity to the neighboring string source/drain nodes.

The above three issues in conventional NAND devices may be undesirable because all transistors within any string do not have any implanted or diffused n-F region as sources/drains, except for the drain of the SSL on the bit line pad side and the source of the GSL at the source contact of the string. That is, junctionless transistors are formed with virtual sources/drains, where the conductivity of source/drain regions depends on the fringe fields from adjacent gates. For example, the source/drain region 113 between an SSL 110A and a GSL gate 109A is in a conductive state only if the fringe field between SSL/GSL gates and the silicon body is strong enough to induce a conductive inversion channel layer within the semiconductor string. Therefore, it may be undesirable if the distance between any point of the source/drain region to the SSL or GSL gate is too large or cannot be reduced freely due to the space that is needed to fit the source contact in.

From an electrostatic point of view, it may also be undesirable for a node to not be biased at a high positive voltage, such as when the source contact is in close vicinity to the source/drain region. The reason is that the overall electric field at the surface of the source/drain region is weakened by the existence of a nearby low-potential node which screens the electric fringe fields of the nearby gates. (The voltage of the source of NAND cell strings, and thus of the source contact, is held at 0 V in most common NAND Flash device operation).

These issues may also be true vice versa for the source nodes 132A-D, as the source nodes 132A-D also may be too far from the next gate and too close to a nearby ground-node silicon body of adjacent strings.

The present disclosure provides a structure and manufacturing method which eases the difficulty of manufacturing narrow pitch island-type SSL gates but at the same time avoids the issues described above.

Embodiments of the present disclosure apply to NAND Flash memory as described above. The definitions given above for single NAND Flash memory cells, cell operation, and NAND cell array organization may apply to the present disclosure. More specifically, the present disclosure may apply to vertical NAND Flash memory of the VG NAND type as described above. At least some disclosed embodiments share some architectural characteristics with conventional VG NAND devices, which were described above in connection with conventional VG NAND.

In one aspect, the disclosed embodiments provide a method for easing the method of narrow pitch node isolation of adjacent island-type SSL gates through arranging strings in a staggered even/odd oriented layout so that double pitch is available to fit in island SSL gates.

In another aspect, the disclosed embodiments provide a vertical structure and manufacturing method to enable the reduction of the space between two gates of a string at a location where a source contact is connected to the source of an adjacent string.

In another aspect, the disclosed embodiments provide a layout with a placement of the source contacts which provides a solution to the potentially negative effects of close vicinity between source contacts and source/drain regions of neighboring strings.

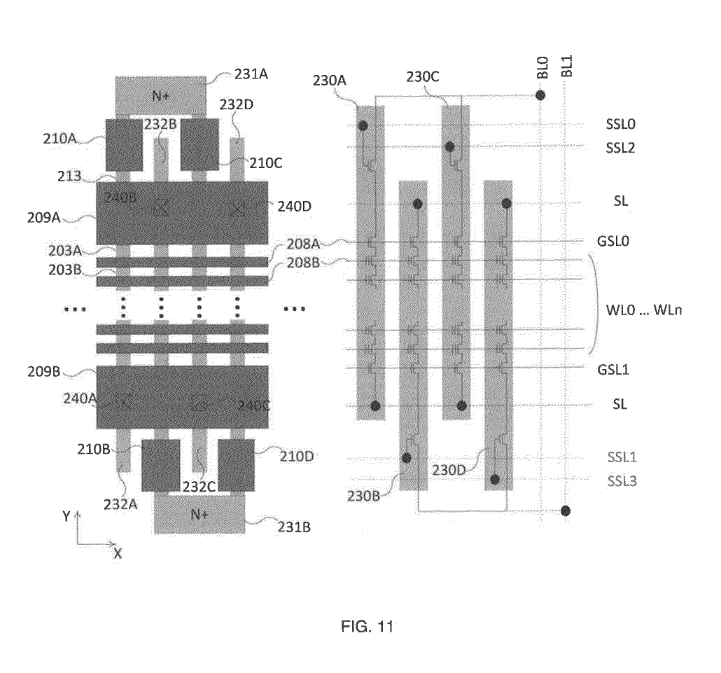

Therefore, the disclosed embodiments provide a solution that avoids some drawbacks of the schemes described above, which also utilizes an even/odd oriented string layout. Features of the disclosed embodiments will be described with respect to the layout shown in FIG. 11.

The layout on the left side of FIG. 11 shows a simplified illustration where for clarity reasons the layout focuses on electrically conductive elements and omits details on the cell structure, dielectric layers, gate dielectrics, charge storage layers, etc. The right side of the figure shows the schematic of the layout. The schematic of FIG. 11 is not different from the schematic of the scheme of FIG. 10 described above. The layout shows some common features with the scheme of FIG. 10, all of which will not be repeated in the following description for brevity reasons.

Even strings 230A/C and odd strings 230B/D run in opposite directions alternatingly and are connected to even bit line pads 231A and odd bit line pads 231B alternatingly. Due to this even/odd layout there exist odd GSL lines 209A and even GSL lines 209B. As even and odd GSL lines run in the horizontal x-direction and are shared by even strings and odd strings alike, each string has a GSL gate at the source side (as in most conventional NAND devices) but also on the drain side. It is to be understood that FIG. 11 shows only one layer out of a plurality of layers that are stacked vertically in a manner similar to that in FIG. 9.

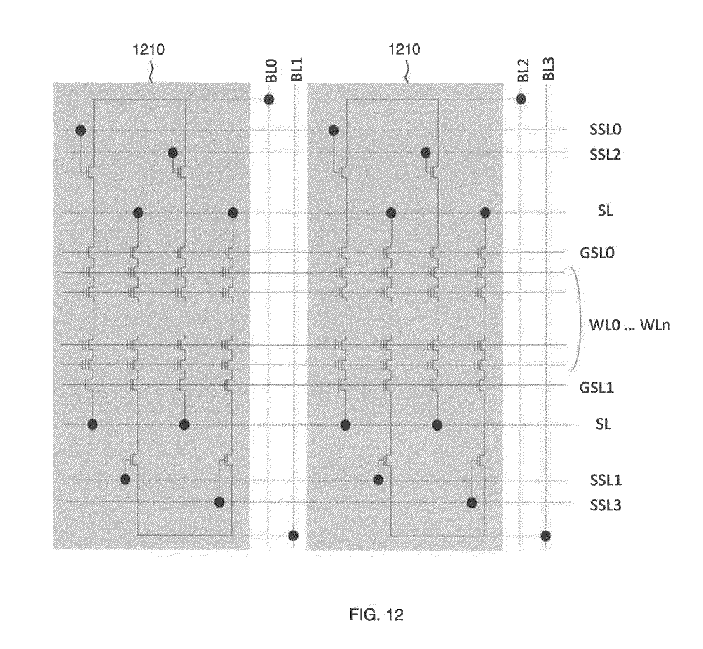

A schematic for two stacked layers is shown in FIG. 12, where each gray-shaded area 1210 represents one layer and the two layers are stacked on top of each other in the real device structure (although in the schematic both layers are drawn in the same plane). Interconnections represented as dashed lines are conductive lines, for example metal lines such as aluminum or copper, located at a vertical level lying above the stacked cell layers and contacted to each respective node in the cell layers through via contacts.

The source lines SL also run as conductive lines and are connected to the source nodes of the strings through source contacts, which also connect all the source nodes of strings that are stacked in a vertical direction with each other, but not source nodes of strings that are located horizontally to each other. In other words, horizontal connections between sources of different strings take place solely through the conductive source lines, but not through the source contacts themselves, as would be the case for example in FIG. 9. That is, the source contacts 240A/C (240B/D) of odd (even) strings in FIG. 11 are formed as individual contacts and are located between adjacent even (odd) strings 230A/C (240B/D), and not as plate-like contacts as in FIG. 9.

Specific to the disclosed embodiments, source contacts may not be located in a gap between SSL gates and GSL gates and may not be in close spatial vicinity of any source/drain regions of adjacent strings. Rather, in one embodiment as shown in FIG. 11, the source contacts run through the GSL gates 209A/B in such a way that the source contacts are screened from the nearest neighboring string by the gate material of the GSL which surrounds the source contacts. For example, the space between the source contact 240B and the body of the string 230A is filled with the gate material of the GSL line 209A.

Although the source contacts 240A-240D run through the GSL gates 209A/B, the source contacts are not in electrical contact with any of the GSL gates, but are isolated from the GSL gates in a manner that will become more apparent with the descriptions and illustrations of vertical cross sections.

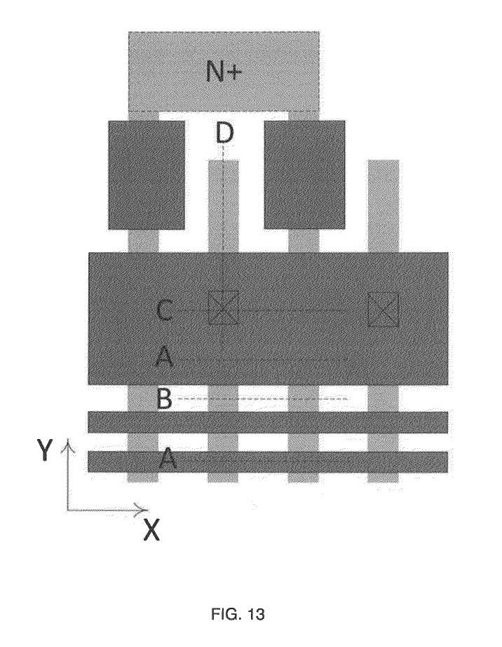

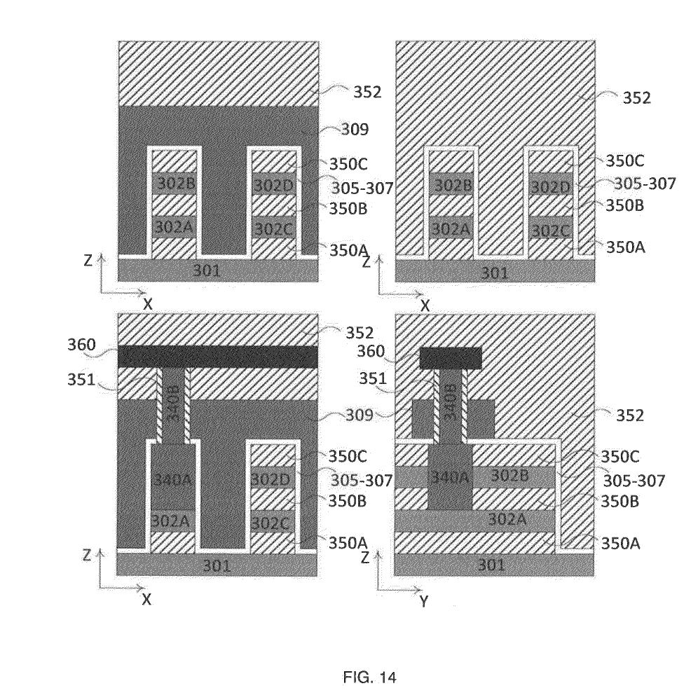

FIG. 13, which replicates part of the layout in FIG. 11, serves for defining cutlines A, B, C and D for the subsequent vertical cross-sectional illustrations. FIG. 14 shows vertical cross sections along cutlines A (upper left), B (upper right), C (lower left) and D (lower right).

The upper left portion of FIG. 14 (cutline A) shows a cross section along either a word line or a GSL line at a location without a source contact. In this example, only two stacked layers are shown for simplicity reasons. However, it is to be understood that the present disclosure applies to any integer number of stacked layers. The cell structure is manufactured on the substrate silicon 301 of the wafer. The structure consists of multiple silicon strips 302A-302D which form the body of the strings. A first string 302A and a second string 302B may be referred to as stacked strings since the first string 302A and the second string 302B overlap one another in the Z-direction. In the vertical direction, strings are isolated from each other and from the substrate silicon 301 by interlayer dielectric layers 350A-350C, which may consist of silicon oxide for example. Thus, the cell stack is a layered structure of alternating semiconductor and dielectric layers. The different dielectric layers 350A-350C are not necessarily of the same material. Especially the topmost dielectric layer may be of a different material from the other interlayer dielectrics, for example silicon nitride or silicon oxynitride.

The stacks are patterned in a way that adjacent strings are also isolated from each other in the X-direction, i.e., the string 302A is isolated from the string 302C and the string 302B is isolated from the string 302D. The stacks thus form fin-shaped structures with their long axis along the Y-direction, which is also the direction in which the cell transistors of each string are connected electrically in series. The fin-shaped stacks are covered by a multi-layered gate dielectric layer 305-307, which is an isolating cover and wraps around the fin-shape in a way that it serves as a gate dielectric for the sidewalls of the silicon strips 302A-302D.

As in other NAND devices, the multiple layers which constitute the gate dielectric serve as tunnel dielectric, charge storage layer, and coupling dielectric (or blocking dielectric) as will be understood by those skilled in the art of NAND Flash devices. For example, this multi-layered structure may be one typical for Silicon-Oxide-Nitride-Oxide-Silicon (SONOS) technology. This multi-layer structure is illustrated, for example, in FIG. 1 and FIG. 2 but is not shown in detail in FIG. 14 for simplicity reasons.

A conductive gate material 309, for example consisting of p-doped poly-Si, covers the gate dielectric layers and thus the fin shapes, such as to serve as the gate material for the cell transistors, SSL transistors, or GSL transistors. The gate material is patterned to form word lines, SSL lines, or GSL lines as shown in the top view layouts of FIG. 11 and FIG. 13. The overall structure of the individual transistors formed at the sidewalls of the silicon strips therefore may have a structure similar to the ones shown in FIG. 1 and FIG. 2. An interlayer dielectric 352, for example silicon oxide, fills the spaces between conductive layers of the stacked cell structure, whereby the interlayer dielectric 352 may be in fact a multi-layered structure.

The upper right portion of FIG. 14 (cutline B) shows the same stacked structure again cut in the X-direction, but in the space between a word line and a GSL line or between two word lines or between SSL gates and a word line. Instead of the gate material 309 filling the space between and above the stack structures, the interlayer dielectric 352 fills the space between the fin-shaped cell stacks. Although this figure is drawn with the gate dielectric layers 305-307, embodiments are possible where these layers are removed at locations without gates, such as locations along cutline B.

The lower left portion of FIG. 14 (cutline C) shows the same stacked structure again cut in the X-direction, again at a location along a GSL line as for cutline A, but specifically cut at a location of a source contact 340A/B and a source line 360. The source line 360 runs as a conductive line, for example a metal line such as copper or aluminum, and for example in the X-direction. A source contact 340A/B connects from the source line 360 through the gate material 309 of the GSL gate to the silicon strips 302A/B of the two strings which are stacked on top of each other in this example. Only the lower silicon strip 302A is visible in this figure.

Although the source contact 340A/B runs through the gate material 309, the source contact 340A/B is not in electrical contact with the gate material 309 as the source contact 340A/B is isolated from the gate material 309 by the dielectric layers 305-307 and 351. The source contact 340A/B can be thought of as having two parts. A bottom part 340A runs between the bottom-most string 302A to the top of the cell stack and is isolated by the gate dielectric layers 305-307 from the gate material 309. A top part 340B runs between the top of the bottom part 340A and the source line 360 and is isolated by another sidewall dielectric 351 from the gate material 309.

The lower right portion of FIG. 14 (cutline D) shows a cross section in the y-direction along a vertical stack comprising strings, at a location where the cut goes through a source contact. While showing essentially the same features as the cross section through cutline C, this view shows with more clarity the fact that the source contact 340A/B is in electrical contact with both the upper string 302B and the lower string 302A. Although the figure is drawn with layers 305-307 covering the stacked structure at all locations regardless of whether this location is covered by the gate material 309 or not, embodiments are also possible where layers 305-307 are removed from all locations except for those covered by the gate layer 309, as mentioned above.

The bottom part 340A of the source contact may consist of n-doped polycrystalline silicon. The top part 340B of the source contact may also consist of n-doped polycrystalline silicon. In another embodiment, the top part 340B of the source contact may be a metal plug as conventionally used in semiconductor manufacturing, such as Ti/TiN/W.

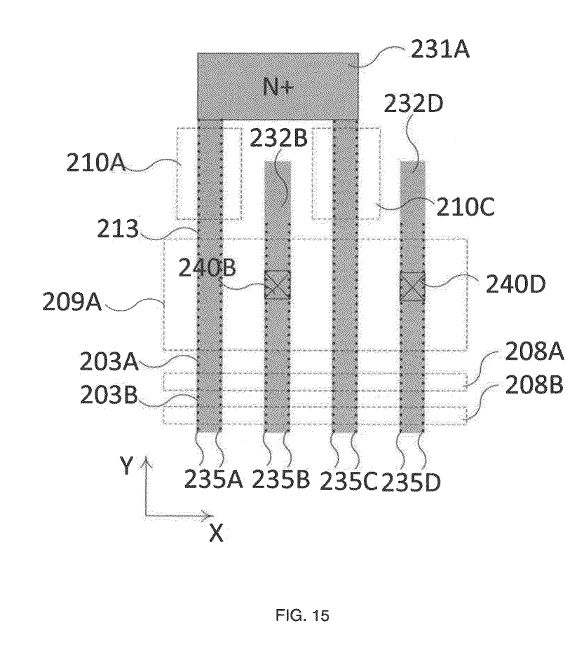

FIG. 15 replicates part of FIG. 11, with gate layers only hinted by dashed lines, to visualize the location of the inversion layer string channels within the silicon strips when all transistors are in a turned on state. Conductive string channels are drawn as the dotted lines 235A-235D. As described above, inversion layer channels exist at all locations of the strings which are covered by gates 208A/B, 209A, 210A/C, but also in source/drain regions which are in close vicinity to turned-on gate nodes, due to the electric fringe fields between the gate and the body nodes. Although the source contacts 240B/D are surrounded by the GSL 209A, the source contacts 240B/D still function as a source node and actually take the place of the source of the GSL gates 209A, with no additional implanted/diffused or fringe-field induced source being necessary. This is possible because inversion layer channels 235B/D extend throughout the entire area covered by the gate 209A up to the point where the inversion layer channels 235B/D connect to the source contacts 240B/D.

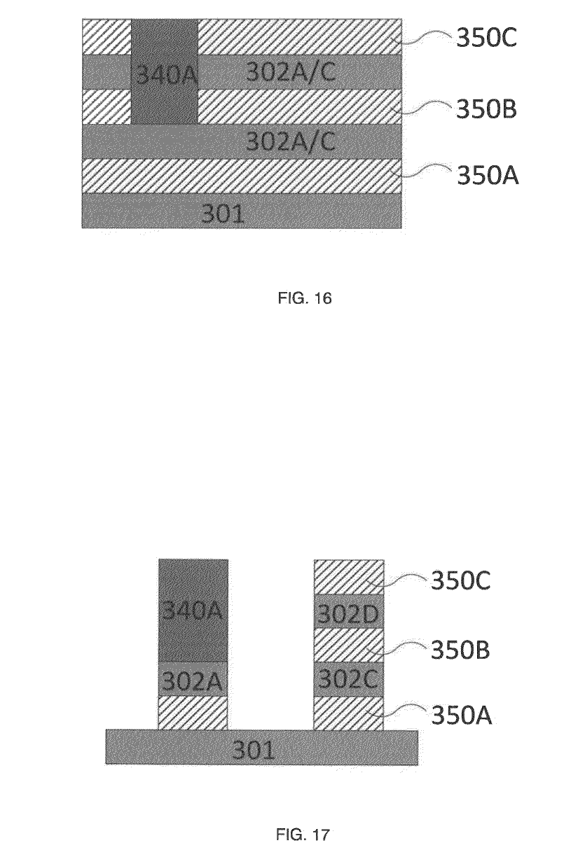

A manufacturing process for manufacturing the structure of embodiments of the present disclosure will now be described. The process is illustrated in FIG. 16 to FIG. 23. The description is intended to provide a specific sequence for manufacturing the source contact and a manner in which the formation of the source contact can fit in to the existing manufacturing process of a VG NAND device without imposing difficulties that cannot be covered by way of existing manufacturing tools or processes. Details of the manufacturing process are shown only to the extent that the details are specific to and relevant for the present disclosure. Numerous details of the manufacturing processes that are not explicitly shown may be of lesser relevance for the applicability of the present disclosure or may be obvious to one skilled in the art. Therefore, it is to be understood that the following description is not intended to show the manufacturing process of the device in its entirety, as at least parts of the basic underlying manufacturing process of the memory device itself are known to those skilled in the art. Numerous manufacturing steps, such as steps that may occur before or after the described steps, may be obvious to one skilled in the art of chip manufacturing and are therefore omitted for brevity. Also, certain details of the shown steps or certain manufacturing steps that occur between the shown steps, such as photolithography steps including photoresist masks, wet cleaning processes, layer deposition, chemical-mechanical polishing processes, metal line manufacturing processes, etc., are sufficiently understood by those skilled in the art such that they are omitted for brevity. Also, steps that are shown as single steps may consist of multiple steps. For example, etch processes that are shown as a single etch step may in fact consist of multiple etch steps for each different material layer. Also, materials shown as a single material may consist of multiple materials, such as contact fillings, gate dielectrics, metal layers, interlayer dielectrics, etc., as will be understood by one skilled in the art of NAND Flash chip manufacturing.

FIG. 16 shows a step after the deposition of the cell stack layers. The figure illustrates the fact that the bottom part 340A of the source contact is manufactured after the stacking of the cell stack layers which will later be the string bodies and the interlayer dielectrics. The figure especially illustrates the fact that the bottom part 340A of the source contact is manufactured before the manufacturing step of the gate dielectric layers 305-307. The bottom part 340A of the source contact is manufactured as a through-hole via that penetrates all silicon layers and all interlayer dielectric layers down to the lowest silicon layer. Although not shown in the figure, it may be obvious and well known in the art that the manufacturing of any via contacts may include numerous detailed steps, for example photolithography and anisotropic single-step or multi-step reactive ion-etching of the contact hole, filling of the contact hole with contact plug material, subsequent etch back, or chemical-mechanical polishing. In this embodiment, the material of the contact filling may be, for example, n-doped poly-Si.

FIG. 17 shows a step where the cell stack is patterned into fin-shaped string patterns. The bottom part 340A of the source contact is integrated in the fin-shaped structure containing the strings which are contacted by the source contact.

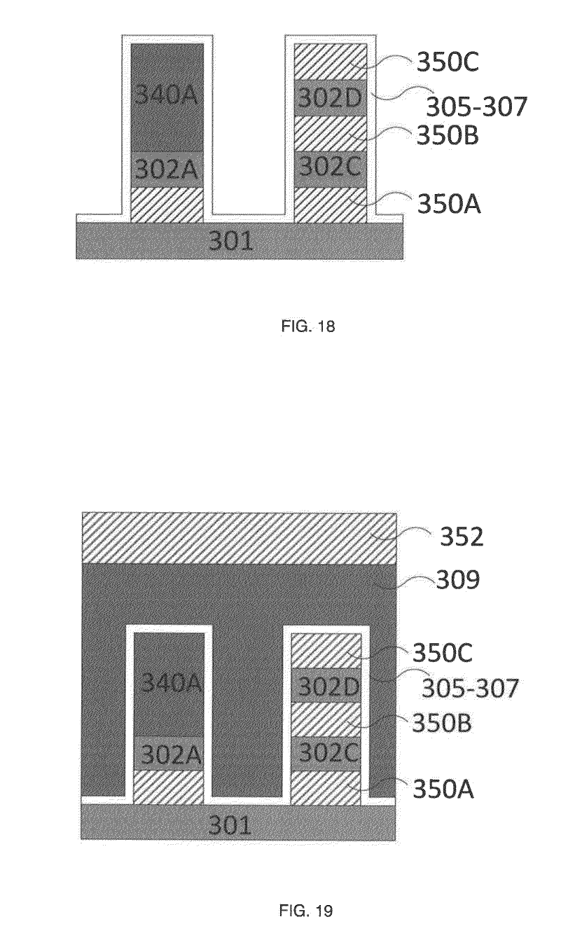

FIG. 18 shows the deposition of the gate dielectric layers 305-307. All parts of the bottom part 340A of the source contact which were exposed in a previous step are completely encapsulated by the gate dielectric so that no part of the bottom part 340A of the source contact is exposed. Thus it can be seen that, on one hand, the bottom part 340A of the source contact establishes electrical connection between vertical layers, and on the other hand, the bottom part 340A of the source contact is isolated to the outside.

FIG. 19 shows a step where the gate 309 is manufactured with the subsequent step of depositing an interlayer dielectric 352. Although not shown in the figure, it may be obvious and well known in the art that the manufacturing of the gate includes multiple steps besides the deposition of the gate material, for example etch back or chemical-mechanical polishing, photolithography, and anisotropic reactive ion-etching to create the word line, SSL and GSL lines. It can be seen that, due to the encapsulating gate dielectric layers 305-307, the source contact 340A and the gate material 309 are isolated from each other.

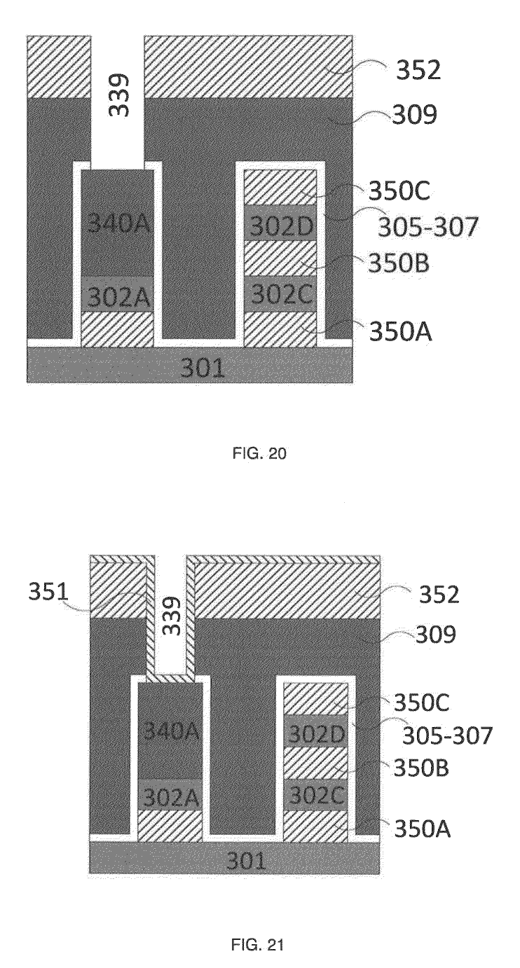

FIG. 20 shows a step where the contact hole 339 which will later become the top part of the source contact is etched through the interlayer dielectric 352, the gate material 309 and the gate dielectric layers 305-307 up to the point where conductive material of the bottom part 340A of the source contact is exposed or partly etched back.

FIG. 21 shows a step where a sidewall spacer 351 consisting of nonconductive material, for example silicon oxide, is deposited in a way that the sidewall spacer 351 covers the sidewalls and bottom of the contact hole 339, but does not entirely fill the hole.

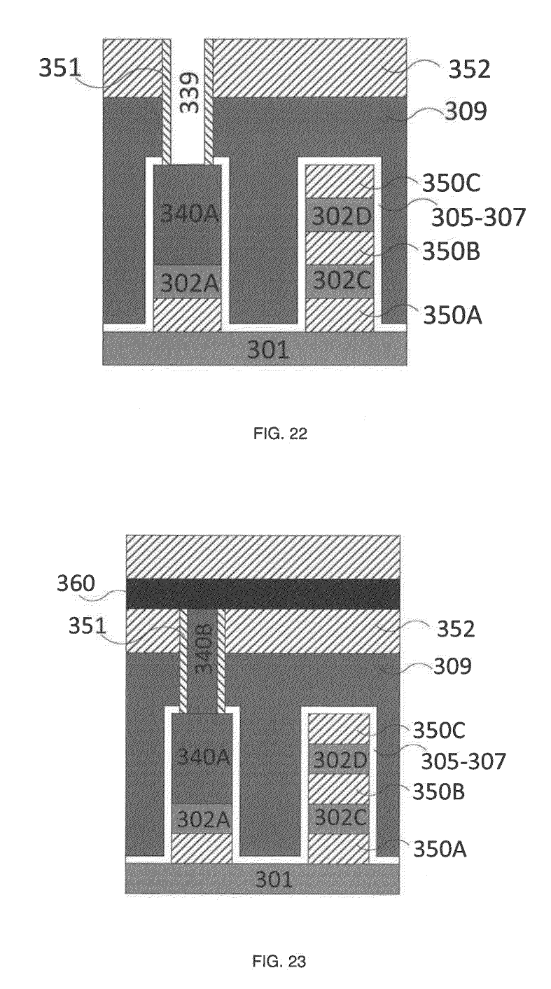

FIG. 22 shows a step where the sidewall spacer material 351 is etched by anisotropic reactive ion etching or anisotropic non-reactive ion etching in a way that the spacer material 351 is removed at all locations except at the sidewalls of the source contact holes by a directional etch process. More specifically, the spacer material 351 at bottom of the top source contact hole 339 is etched away so as to expose the conductive material of the bottom part 340A of the source contact.

FIG. 23 shows the step of filling the top source contact hole 339 with conductive material and thus finalizing the formation of the top source contact 340B. The figure also shows subsequent steps of source line 360 formation and interlayer dielectric formation without the details of these subsequent steps. As in the previous steps, numerous intermediate steps are omitted but may be obvious to one skilled in the art of semiconductor chip manufacturing.

Summarizing, it may be apparent from the description of the manufacturing process that the formation of the source contacts and the gates occurs in a process divided into two parts (bottom and top contact formation) with the gate dielectric and gate formation between these two partial processes. The process may occur with the following underlying sequence: bottom contact conductive plug formation, then bottom contact encapsulating isolation layer formation, then gate formation, then top contact isolation spacer formation, and then top contact conductive plug formation.

It may be apparent from the description herein that the disclosed method of manufacturing ensures that the source contact 340A/B establishes electrical connections between the sources of strings 302A/C belonging to all layers and the source line 360. At the same time, the described method ensures that the source contact is reliably isolated from the nearby gate node 309 of the GSL lines.

Generally, embodiments of the present disclosure provide a method of easing the difficulty of narrow pitch manufacturing, especially of isolating adjacent island-type SSL gates from each other in a VG NAND vertical structure by way of utilizing an alternating even/odd string orientation layout. At the same time, embodiments of the present disclosure make the application of such an alternating even/odd string orientation more feasible by providing an improved layout which avoids at least some of the potentially negative effects seen in schemes described above.

In a conventional scheme, the space between the SSL and GSL gates in the Y-direction is significantly larger than the spaces between any other gates within the strings, e.g., between the word lines or between the GSL and the word lines, because a sufficiently large distance needs to exist between SSL and GSL gates to allow for the space needed to fit in source contacts and leave a sufficient space margin between the source contacts and adjacent gates.

In the present embodiments, the minimum space between SSL and GSL gates is not delimited by the existence of source contacts, since electrical isolation between the source contacts and gate nodes is not achieved by providing for sufficient space margin, but through a spacer isolation scheme and two-step manufacturing method as described. Thus, the space between SSL and GSL gates can be flexibly chosen, as is the case between any other gates of the cell strings. The length of the virtual source regions of the SSL gates can therefore be flexibly reduced to a length close or equal to the minimum feature size of the used photolithography tool and can thus be sufficiently small to enhance the induction of a fringe-field induced inversion layers in the source/drain regions.

In a conventional scheme, the source contacts are in close vicinity in the X-direction to the semiconductor surface of neighboring string bodies, which may be undesirable for the reasons given above.

In the present embodiments, the fact that the source contacts can be freely located in the layout to overlap with GSL gates may be utilized to place the source contacts such that gate material of the GSL is between the source contact and the adjacent string body and thus screens the source contacts and the adjacent strings from each other. In an embodiment, the source contacts fully overlap with the GSL gates in a manner such that the source contacts are completely surrounded by gate material in all horizontal directions. Thus, even though the source contacts may still be in close spatial vicinity to neighboring strings, the source contacts can be screened from an electrostatic point of view, so as not to inhibit any fringe-field induced formation of virtual source/drains.

Embodiments of the present disclosure also provide a vertical structure and manufacturing process, which make the realization of the above layouts possible, including methods to make connections between layers belonging to the same node and isolating layers that do not belong to the same node. This being said, even if neither of the two aforementioned results is provided, the disclosed manufacturing process may still provide the following impact: the process may provide protection against shorts between the source nodes and the gate nodes. The process may do this without imposing unfeasibly difficult processes on the lithography tools or imposing misalign margins that lie beyond the minimum attainable feature sizes of the used lithography technology and by combining single process steps that are, by themselves, known to those skilled in the art of semiconductor manufacturing.

In an embodiment, various features of the present disclosure may be combined in an optimal way, such as complete overlap of source contacts and GSL gates, reduction of space between SSL and GSL gates, a proposed vertical structure, and a proposed manufacturing process. Even if the above features, which are all beneficial by themselves, are not fully utilized in their entirety, and only a portion of the features are implemented while others are not, the present disclosure still applies. Several design variations will now be discussed.

In a first embodiment, the source contact is described as being completely surrounded by the gate material of the GSL gate. As described, this configuration is made possible through the disclosed manufacturing method by which the source contact is isolated from any of the nearby gate nodes, regardless of the degree of overlap between the source contact and any gate node.

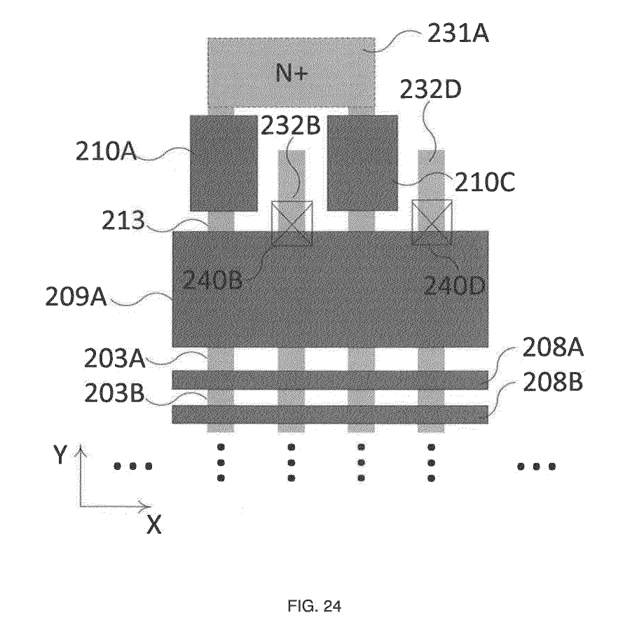

A second embodiment is shown in FIG. 24, where the source contacts 240B/D are only in partial overlap with the GSL gate 209A. The space between the SSL gates 210A/C and the GSL 209A in the Y direction is still smaller than would be required if the node isolation between the source contacts and gate nodes relied purely on sufficient space and misalign margin. In this regard, there is no difference between the first and second embodiments.

At least a portion of the impact of embodiments disclosed herein may be lost in this second embodiment, because the source contacts are not completely screened in all horizontal directions, and therefore parts of the source contacts face adjacent strings. However, this embodiment still retains at least a portion of the effects disclosed herein. Even a partial screening may be beneficial, because the space between SSL and GSL gates is not delimited by the existence of source contacts, since electrical isolation between the source contacts and gate nodes is not achieved by providing for sufficient space margin but through a spacer isolation scheme and two-step manufacturing method as described.

In the first and second embodiments, the source contact is described as being completely surrounded by the gate material of the GSL gate, and the space between SSL and GSL gates in the y-direction is described as being close to the minimum attainable space of the used lithography technology and as not being larger than between GSL and word lines or between word lines. As described, this is made possible through the proposed manufacturing method by which the source contact is isolated from any of the nearby gate nodes, regardless of the degree of overlap between the source contact and any gate node.

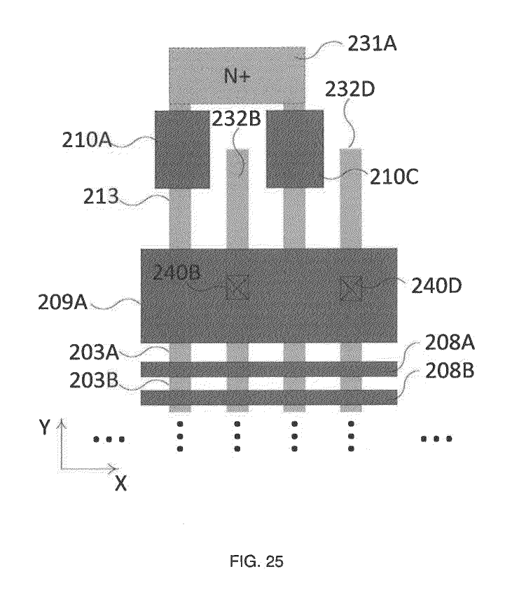

A third embodiment, which provides for only part of the effects of the disclosed concepts, is shown in FIG. 25. In this embodiment, the source contacts 240B/D are completely surrounded by the GSL 209A as in the first embodiment. However, the spaces in the y-direction between the SSL gates 210A/C and the GSL 209A are significantly wider than the spaces between, for example, the GSL 209A and the word line 203A or between word lines. This means that the node isolation method of the disclosed manufacturing method is not utilized to reduce the space between the SSL and GSL gates but only to manufacture the source contacts in such a way that they are surrounded and screened by the GSL gates.

At least a portion of the impact of embodiments disclosed herein may be lost in this third embodiment, because the space between the SSL and GSL gates is not reduced to enhance the formation of virtual fringe-field induced source/drains during operation. However, this embodiment still retains at least a portion of the effects disclosed herein, because source contacts are screened from the source/drain regions of adjacent strings in their vicinity.

Thus, it may be apparent from the second and third embodiments that the present disclosure still applies in cases that are variations in layout where only partial effect is taken from the disclosed manufacturing scheme. By the same logic, it is also possible that partial effect may be taken of the present disclosure by utilizing a layout with overlapping source contacts and gates and/or with reduced gate-to-gate spacing, but by way of a manufacturing procedure that differs from procedure disclosed herein.

As long as the disclosed two-step process for node isolation of the source contacts with the disclosed order of manufacturing the contact plugs and insulating layers between contacts and gates is retained, numerous variations of this scheme are possible. It may be apparent to one skilled in the art that some details of the disclosed manufacturing method may be essential for the disclosed embodiments to work, while others can be varied. For example, the order of numerous steps which are not directly related to the disclosed embodiments may be interchanged and may be subject to numerous variations as known in the art of chip manufacturing.

Although the drawings used for describing the first embodiment show the size of the bottom part of the contact, for example 340A in FIG. 14, as being exactly the same size as the vertical structure of the stacked strings, contacts can be of various sizes, either narrower or wider than the strings.

Although the embodiments are described with the bottom part of the source contact penetrating through the silicon strips of the different vertical layers, the bottom part can also be manufactured as wrapping around the silicon strips and thus establishing electrical contacts with the different layers, as long as the subsequent step of encapsulating with an insulating layer is kept.

The organization of the cell array with the number of stacked layers, the number of strings per bit line pad, etc., in the disclosed embodiments are to be understood as examples and not to be restricting the disclosed embodiments.

In an embodiment, a memory device is provided. The memory device comprises a substrate silicon; a first stack of strings that comprises a first dielectric layer deposited on the substrate silicon, a first silicon strip deposited on the first dielectric layer, a second dielectric layer deposited on the first silicon strip, a second silicon strip deposited on the second dielectric layer, and a third dielectric layer deposited on the second silicon strip; a second stack of strings that comprises a fourth dielectric layer deposited on the substrate silicon, a third silicon strip deposited on the fourth dielectric layer, a fifth dielectric layer deposited on the third silicon strip, a fourth silicon strip deposited on the fifth dielectric layer and a sixth dielectric layer deposited on the fourth silicon strip; an isolating cover coating the first stack of strings and the second stack of strings; a conductive gate material covering the isolating cover; a conductive source line; and a source contact electrically isolated from the conductive gate material, and the source contact also electrically connecting the conductive source line to the first silicon strip and the second silicon strip through the conductive gate material.

In another embodiment, a method is provided. The method comprises manufacturing a through hole in a stack of alternating layers of semiconductor layers and dielectric layers, the stack of alternating layers of semiconductor and dielectric layers fabricated on a substrate silicon, the through hole extending from a topmost layer to a lowest semiconductor layer of the alternating layers; filling the through hole with a contact material; removing portions of the stack of alternating layers of semiconductor and dielectric layers, forming a first stack of strings and a second stack of strings, the first stack of strings comprising the contact material; depositing an isolating layer on exposed portions of the first stack of strings, the second stack of strings, and the substrate silicon; depositing a gate material on the isolating layer; depositing an interlayer dielectric on the gate material; etching a contact hole through the interlayer dielectric, the gate material, and the isolating layer to an upper portion of the contact material; depositing a side wall spacer comprising nonconductive material on sidewalls and bottom of the contact hole; etching the side wall spacer on the bottom of the contact hole, exposing the upper portion of the contact material; and filling the contact hole with a conductive material.

In another embodiment, a three-dimensional NAND memory array is provided. The three-dimensional NAND memory array comprises a chip substrate and a source contact that at least partially overlaps, relative to a direction perpendicular to the chip substrate, with a gate layer in the three-dimensional NAND memory array to which a gate of a ground select transistor is connected, wherein a stack of strings in the three-dimensional NAND memory array is stacked upwards from the chip substrate.

At least one embodiment is disclosed and variations, combinations, and/or modifications of the embodiment(s) and/or features of the embodiment(s) made by a person having ordinary skill in the art are within the scope of the disclosure. Alternative embodiments that result from combining, integrating, and/or omitting features of the embodiment(s) are also within the scope of the disclosure. Where numerical ranges or limitations are expressly stated, such express ranges or limitations should be understood to include iterative ranges or limitations of like magnitude falling within the expressly stated ranges or limitations (e.g., from about 1 to about 10 includes, 2, 3, 4, etc.; greater than 0.10 includes 0.11, 0.12, 0.13, etc.). For example, whenever a numerical range with a lower limit, Rₗ, and an upper limit, Rᵤ, is disclosed, any number falling within the range is specifically disclosed. In particular, the following numbers within the range are specifically disclosed: R=Rₗ+k*(Rᵤ−Rₗ), wherein k is a variable ranging from 1 percent to 100 percent with a 1 percent increment, i.e., k is 1 percent, 2 percent, 3 percent, 4 percent, 5 percent, . . . , 50 percent, 51 percent, 52 percent, . . . , 95 percent, 96 percent, 97 percent, 98 percent, 99 percent, or 100 percent. Moreover, any numerical range defined by two R numbers as defined in the above is also specifically disclosed. Use of the term “optionally” with respect to any element of a claim means that the element is required, or alternatively, the element is not required, both alternatives being within the scope of the claim. Use of broader terms such as comprises, includes, and having should be understood to provide support for narrower terms such as consisting of, consisting essentially of, and comprised substantially of. Accordingly, the scope of protection is not limited by the description set out above but is defined by the claims that follow, that scope including all equivalents of the subject matter of the claims. Each and every claim is incorporated as further disclosure into the specification and the claims are embodiment(s) of the present disclosure.

The embodiments described herein are examples of structures, systems or methods having elements corresponding to elements of the techniques of this application. This written description may enable those skilled in the art to make and use embodiments having alternative elements that likewise correspond to the elements of the techniques of this application. The intended scope of the techniques of this application thus includes other structures, systems or methods that do not differ from the techniques of this application as described herein, and further includes other structures, systems or methods with insubstantial differences from the techniques of this application as described herein.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A memory device comprising:
a substrate silicon;
a first stack of strings comprising:
a first dielectric layer deposited on the substrate silicon;
a first silicon strip deposited on the first dielectric layer;
a second dielectric layer deposited on the first silicon strip;
a second silicon strip deposited on the second dielectric layer; and
a third dielectric layer deposited on the second silicon strip;
a second stack of strings comprising:
a fourth dielectric layer deposited on the substrate silicon;
a third silicon strip deposited on the fourth dielectric layer;
a fifth dielectric layer deposited on the third silicon strip;
a fourth silicon strip deposited on the fifth dielectric layer; and
a sixth dielectric layer deposited on the fourth silicon strip;
an isolating cover coating the first stack of strings and the second stack of strings;
a conductive gate material covering the isolating cover;
a conductive source line; and
a source contact electrically isolated from the conductive gate material, and the source contact also electrically connecting the conductive source line to the first silicon strip and the second silicon strip through the conductive gate material.

2. The memory device of claim 1, wherein a first part of the source contact is electrically isolated from the conductive gate material by the isolating cover and a second part of the source contact is electrically isolated from the conductive gate material by a sidewall nonconductive layer.

3. The memory device of claim 1, wherein the first dielectric layer comprises a first type of material, and wherein the third dielectric layer comprises a second type of dielectric material.

4. The memory device of claim 1, wherein the isolating cover is a multi-layered gate dielectric and comprises a tunnel dielectric, a charge storage layer, and a coupling dielectric.

5. The memory device of claim 1, further comprising:
a ground select line at one end of the first stack of strings; and
a first string select line island at the other end of the first stack of strings.

6. The memory device of claim 5, further comprising:
a second string select line island, different than the first string select line island, and
wherein the ground select line is also at one end of the second stack of strings, and the second string select line island is at the other end of the second stack of strings.

7. A method comprising:
manufacturing a through hole in a stack of alternating layers of semiconductor layers and dielectric layers, the stack of alternating layers of semiconductor and dielectric layers fabricated on a substrate silicon, the through hole extending from a topmost layer to a lowest semiconductor layer of the alternating layers;
filling the through hole with a contact material;
removing portions of the stack of alternating layers of semiconductor and dielectric layers, forming a first stack of strings, and a second stack of strings, the first stack of strings comprising the contact material;
depositing an isolating layer on exposed portions of the first stack of strings, the second stack of strings, and the substrate silicon;
depositing a gate material on the isolating layer;
depositing an interlayer dielectric on the gate material;
etching a contact hole through the interlayer dielectric, the gate material and the isolating layer to an upper portion of the contact material;
depositing a side wall spacer comprising nonconductive material on sidewalls and bottom of the contact hole;
etching the side wall spacer on the bottom of the contact hole, exposing the upper portion of the contact material; and
filling the contact hole with a conductive material.

8. The method of claim 7, wherein the topmost layer comprises a type of dielectric material.

9. The method of claim 7, wherein the isolating layer is a gate dielectric layer and comprises a tunnel dielectric, a charge storage layer, and a coupling dielectric.

10. The method of claim 7, wherein the contact material comprises a n-doped polycrystalline silicon, and the conductive material comprises n-doped polycrystalline silicon.

11. The method of claim 7, wherein the contact material comprises a n-doped polycrystalline silicon, and the conductive material comprises a metal plug.

12. The method of claim 7, wherein the manufacturing of the through hole occurs prior to the removing the portions of the stack of alternating layers.

13. The method of claim 7, wherein the manufacturing of the through hole occurs after the removing the portions of the stack of alternating layers.

14. A three-dimensional NAND memory array comprising:
a chip substrate; and
a source contact that at least partially overlaps, relative to a direction perpendicular to the chip substrate, with a gate layer in the three-dimensional NAND memory array to which a gate of a ground select transistor is connected, and
wherein a stack of strings in the three-dimensional NAND memory array is stacked upwards from the chip substrate.

15. The memory array of claim 14, wherein the source contact entirely overlaps, relative to the direction perpendicular to the chip substrate, with the gate layer.

16. The memory array of claim 14, wherein the source contact only partially overlaps, relative to a direction perpendicular to the chip substrate, the gate layer.

17. The memory array of claim 14, wherein the source contact passes through the gate layer but is electrically isolated from the gate layer by a dielectric layer surrounding the source contact.

18. The memory array of claim 14, wherein the source contact electrically contacts at least one string of the memory array.

19. The memory array of claim 18, wherein the source contact is electrically screened from a neighboring string of the at least one string by the gate material of the gate layer.

20. The memory array of claim 14, wherein a plurality of strings in the memory array are arranged in an even/odd layout, source contacts of even strings are formed as individual contacts located between adjacent even strings, and source contacts of odd strings are formed as individual contacts located between adjacent odd strings.

21. The memory array of claim 14, wherein the source contact comprises a lower portion and an upper portion, the lower portion being disposed between the lowest and highest portions of the stack of strings and electrically isolated from a gate material by a gate dielectric layer, and the upper portion being disposed between the lower portion and a source line and electrically isolated from the gate material by a sidewall dielectric.
